(19) United States
(12) Patent Application Publication
(10) Pub. No.: US 2007/0090484 A1
(43) Pub. Date: Apr. 26, 2007

(54) INTEGRATED CIRCUIT STRESS CONTROL SYSTEM

(75) Inventors: Jae Gon Lee, Singapore (SG); Cher Sian Chua, Singapore (SG); Chew Hoe Ang, Singapore (SG); Liang-Choo Hsia, Singapore (SG)

Correspondence Address: ISHIMARU & ZAHRT LLP, 333 W. EL CAMINO REAL, SUITE 330, SUNNYVALE, CA, 94087, US

(73) Assignee: CHARTERED SEMICONDUCTOR MANUFACTURING, LTD., Singapore (SG)

(21) Appl. No.: 11/162,027

(22) Filed: Aug. 25, 2005

(51) Int. Cl. H01L 29/00

(52) U.S. Cl. 257/510

(57) ABSTRACT

An integrated circuit stress control system is provided. A gate is formed on a substrate and a channel is formed in the substrate. A source/drain is formed around the gate. A shallow trench isolation is formed in the substrate, the shallow trench isolation producing strain on the channel. A stress suppressing feature is formed in the substrate.

### TECHNICAL FIELD

The present invention relates generally to semiconductor transistors, and more particularly to transistor structures for integrated circuits.

### BACKGROUND ART

At the present time, electronic products are used in almost every aspect of life, and the heart of these electronic products is the integrated circuit. Integrated circuits are used in everything from airplanes and televisions to wristwatches.

Integrated circuits are made in and on silicon wafers by extremely complex systems that require the coordination of hundreds or even thousands of precisely controlled processes to produce a finished semiconductor wafer. Each finished semiconductor wafer has hundreds to tens of thousands of integrated circuits, each wafer worth hundreds or thousands of dollars.

Integrated circuits are made up of hundreds to millions of individual components. One common component is the semiconductor transistor. The most common and important semiconductor technology presently used is silicon-based, and the most preferred silicon-based semiconductor device is a complementary metal oxide semiconductor (“CMOS”) transistor.

CMOS transistors are generally divided into two classes, metal oxide semiconductor with n-type channel (“NMOS”) and metal oxide semiconductor with p-type channel (“PMOS”). NMOS is a device where electrons are responsible for conduction. On the other hand, PMOS is a device where holes are responsible for conduction.

The principal elements of a CMOS transistor generally consist of a silicon substrate having transistor areas. The transistor areas contain polysilicon gates on silicon oxide gates, or gate oxides, over the silicon substrate. The silicon substrate on both sides of the polysilicon gate is lightly doped to become conductive. These lightly doped regions of the silicon substrate are referred to as “shallow source/drain”, which are separated by a channel region beneath the polysilicon gate. A curved silicon oxide or silicon nitride spacer, referred to as a “sidewall spacer”, on the sides of the polysilicon gate allows deposition of additional doping to form more heavily and deeply doped regions of the shallow source/drain (“S/D”), which are called “deep S/D”.

To complete the transistor, a silicon oxide dielectric layer is deposited to cover the polysilicon gate, the curved spacer, and the silicon substrate. To provide electrical connections for the transistor, openings are etched in the silicon oxide dielectric layer to the polysilicon gate and the S/D. The openings are filled with metal to form electrical contacts. To complete the integrated circuits, the contacts are connected to the outside of the dielectric material through additional levels of wiring in additional levels of dielectric material.

Another key issue for fabrication of CMOS is mechanisms to improve performance. One way to improve performance is to control strain in the channel. Increasing strain to the channel improves performance in PMOS. PMOS strain can be increased, for example, by incorporating a shallow trench isolation (“STI”). However, decreasing strain to the channel improves performance in NMOS. Thus, it is counterproductive to incorporate an STI into an NMOS device.

An integrated circuit contains many NMOS and PMOS devices. If STIs are incorporated to improve PMOS device performance, NMOS device performance will be degraded. What is needed is a way to enable STIs to be incorporated to improve PMOS device performance without degrading NMOS device performance.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit stress control system. A substrate is provided. A gate is formed on the substrate and a channel is formed in the substrate. A source/drain is formed around the gate. A shallow trench isolation is formed in the substrate, the shallow trench isolation producing strain on the channel. A stress suppressing feature is formed in the substrate.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a cross section of an integrated circuit according to an embodiment of the present invention, the cross section being taken along line 1-1 in FIG. 2;

FIG. 2 is a top view of the integrated circuit of FIG. 1;

FIG. 3 is a top view of an integrated circuit according to an alternate embodiment of the present invention; and

FIG. 4 is a flow chart of a method for an integrated circuit stress control system in accordance with the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the device are semi-diagrammatic and not to scale and, particularly, some of the dimensions are for the clarity of presentation and are shown greatly exaggerated in the FIGs. In addition where multiple embodiments are disclosed and described having some features in common, for clarity and ease of illustration, description, and comprehension thereof, like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

Integrated circuits are made up of hundreds to millions of individual components. One common component is the semiconductor transistor. The most common and important semiconductor technology presently used is silicon (“Si”) based, and the most preferred Si based semiconductor device is a complementary metal oxide semiconductor (“CMOS”) transistor.

CMOS transistors are generally divided into two classes, metal oxide semiconductor with n-type channel (“NMOS”) and metal oxide semiconductor with p-type channel (“PMOS”). NMOS is a device where electrons are responsible for conduction. On the other hand, PMOS is a device where holes are responsible for conduction.

The principal elements of a CMOS transistor generally consist of a Si substrate having transistor areas. The transistor areas contain polysilicon gates on silicon oxide gates, or gate oxides, over the Si substrate. The Si substrate on both sides of the polysilicon gate is lightly doped to become conductive. These lightly doped regions of the Si substrate are referred to as “shallow source/drain”, which are separated by a channel region beneath the polysilicon gate. A curved silicon oxide or silicon nitride spacer, referred to as a “sidewall spacer”, on the sides of the polysilicon gate allows deposition of additional doping to form more heavily and deeply doped regions of the shallow source/drain (“S/D”), which are called “deep S/D”.

To complete the transistor, a silicon oxide dielectric layer is deposited to cover the polysilicon gate, the curved spacer, and the Si substrate. To provide electrical connections for the transistor, openings are etched in the silicon oxide dielectric layer to the polysilicon gate and the S/D. The openings are filled with metal to form electrical contacts. To complete the integrated circuits, the contacts are connected to the outside of the dielectric material through additional levels of wiring in additional levels of dielectric material.

Another key issue for fabrication of CMOS is mechanisms to improve performance. One way to improve performance is to control strain in the channel. Increasing strain to the channel improves performance in PMOS. PMOS strain can be increased, for example, by incorporating a shallow trench isolation (“STI”). However, decreasing strain to the channel improves performance in NMOS. Thus, conflicts with strain optimization can occur within integrated circuits incorporating both PMOS and NMOS.

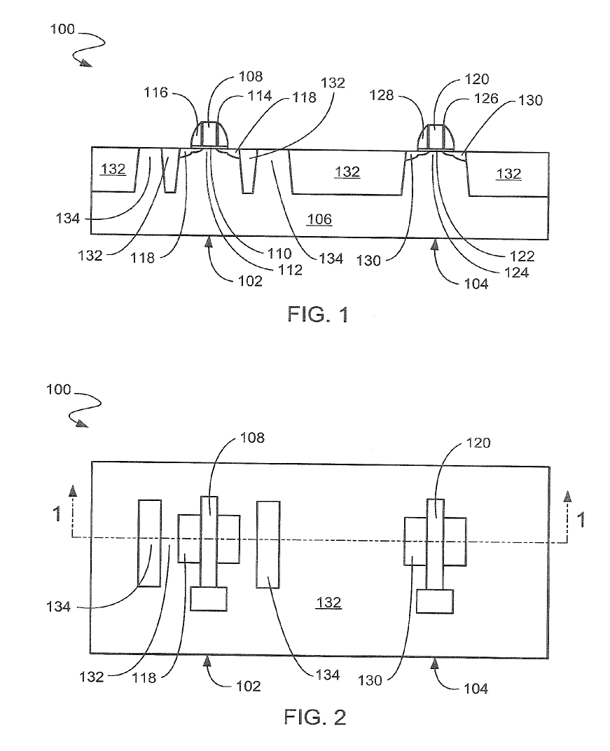

Referring now to FIG. 1, therein is shown a portion of a cross section of an integrated circuit (“IC”) 100 taken along line 1-1 in FIG. 2, according to an embodiment of the present invention. Standard processes, such as photolithography, form an NMOS transistor 102 and a PMOS transistor 104 in a substrate 106.

In this embodiment, the NMOS transistor 102 has an NMOS gate 108. Below the NMOS gate 108 is an NMOS gate oxide 110, and below the NMOS gate oxide 110 is an NMOS channel 112. Surrounding the NMOS gate 108 is an NMOS liner 114, and surrounding the NMOS liner 114 is an NMOS spacer 116. An NMOS source/drain 118 extends from the NMOS channel 112 in the substrate 106.

The PMOS transistor 104 has a PMOS gate 120. Below the PMOS gate 120 is a PMOS gate oxide 122, and below the PMOS gate oxide 122 is a PMOS channel 124. Surrounding the PMOS gate 120 is a PMOS liner 126, and surrounding the PMOS liner 126 is a PMOS spacer 128. A PMOS source/drain 130 extends from the PMOS channel 124 in the substrate 106.

A shallow trench isolation (“STI”) 132 in the substrate 106 surrounds the NMOS transistor 102 and the PMOS transistor 104. In this embodiment, the STI 132 is made of silicon dioxide (“SiO₂”) and the substrates 106 is made of Si. Thus, the difference in thermal expansion between the SiO₂ and the Si produces strain in the PMOS channel 124 and in the NMOS channel 112. Strain in the PMOS channel 124 improves performance by increasing hole mobility. However, strain in the NMOS channel 112 degrades performance by reducing electron mobility.

It has been unexpectedly discovered that incorporating a stress suppressing feature 134, which is generally rectangular, parallel to the length of the NMOS gate 108 and in the STI 132 reduces strain to the NMOS channel 112. Thus, the stress suppressing feature 134 is perpendicular to the direction of the strain. The stress suppressing feature 134 acts similarly as a bulwark in the sea that is used to suppress the tide from the sea. Likewise, the stress suppressing feature 134, in the vicinity thereof, suppresses the strain generated by the STI 132.

In one embodiment, the stress suppressing feature 134 is formed during photolithographic processes used to form the STI 132. A mask is used to shield the regions where the stress suppressing feature 134 will be formed. The STI 132 is then formed around the stress suppressing feature 134. Thus in this embodiment, the stress suppressing feature 134 is a region of the substrate 106 that has not been formed into the STI 132, but instead remains unaltered by the STI-forming process.

The distance between the stress suppressing feature 134 and the NMOS transistor 102 affects the strain on the NMOS transistor 102. Strain increases as the distance increases. Thus, strain is controlled, adjusted to a predetermined level, and optimized by adjusting the position of the stress suppressing feature 134 and adjusting the distance between the stress suppressing feature 134 and the NMOS transistor 102.

Referring now to FIG. 2, therein is shown a top view of the IC 100. The STI 132 surrounds the NMOS transistor 102 and the PMOS transistor 104. The PMOS source/drain 130 are on either side of the PMOS gate 120. The NMOS source/drain 118 are on either side of the NMOS gate 108. The stress suppressing features 134 are on either side of the NMOS transistor 102, positioned parallel to the direction of the NMOS gate 108, and perpendicular to the direction of the strain.

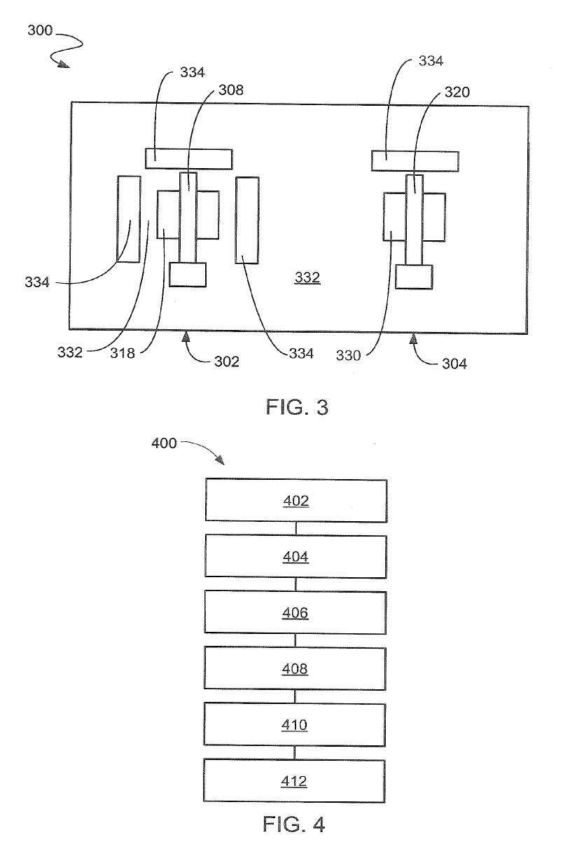

Referring now to FIG. 3, therein is shown a top view of an IC 300 according to an alternate embodiment of the present invention. An STI 332 surrounds an NMOS transistor 302 and a PMOS transistor 304. The STI 332 produces strain in the NMOS transistor 302 and the PMOS transistor 304.

The NMOS transistor 302 is comprised of an NMOS gate 308, and an NMOS source/drain 318 is on either side of the NMOS gate 308. In this embodiment, stress suppressing features 334 surround the NMOS transistor 302. Thus the stress suppressing features 334 lie perpendicular and parallel to the NMOS gate 308.

Electron mobility in the NMOS transistor 302 is degraded when stress is applied in both perpendicular and parallel directions to the NMOS gate 308. Thus, the stress suppressing features 334 reduce the stress in both the perpendicular and parallel directions.

The PMOS transistor 304 is comprised of a PMOS gate 320, and a PMOS source/drain 330 is on either side of the PMOS gate 320. In this embodiment, the stress suppressing feature 334 lies perpendicular to the PMOS gate 320 and parallel to the direction of the strain.

Hole mobility is degraded, and thus performance is degraded, when stress is applied parallel to the PMOS gate 320. On the other hand, hole mobility is improved, and thus performance is improved, when stress is applied perpendicular to the PMOS gate 320. Thus, performance of the PMOS transistor 304 is increased when the stress suppressing feature 334 lies perpendicular to the PMOS gate 320 and does not lie parallel to the PMOS gate 320.

Referring now to FIG. 4, therein is shown a flow chart of a system 400 for an integrated circuit stress control system in accordance with the present invention. The system 400 includes providing a substrate in a block 402; forming a gate on the substrate in a block 404; forming a channel in the substrate in a block 406; forming a source/drain around the gate in a block 408; forming a shallow trench isolation in the substrate, the shallow trench isolation producing strain on the channel in a block 410; and forming a stress suppressing feature in the substrate in a block 412.

In greater detail, an integrated circuit stress control system, according to the present invention, is performed as follows:
(1) 1. As shown in FIG. 1, the substrate 106 is provided and the NMOS channel 112 and the PMOS channel 124 are formed in the substrate 106. The NMOS gate oxide 110 is formed over the NMOS channel 112, and the PMOS gate oxide 122 is formed over the PMOS channel 124. The NMOS gate 108 is formed on the NMOS gate oxide 110, and the PMOS gate 120 is formed on the PMOS gate oxide 122. The NMOS liner 114 is formed around the NMOS gate 108, and the PMOS liner 126 is formed around the PMOS gate 120. The NMOS spacer 116 is formed on the NMOS liner 114, and the PMOS spacer 128 is formed on the PMOS liner 126. The NMOS source/drain 118 is formed around the NMOS gate 108, and the PMOS source/drain 130 is formed around the PMOS gate 120. The shallow trench isolation 132, producing strain on the NMOS channel 112 and the PMOS channel 124, is formed in the substrate 106. In addition, a stress suppressing feature 134, relieving strain from the NMOS channel 112, is formed in the substrate 106 and parallel to the NMOS gate 108.
(2) 2. As shown in FIG. 3, elements are provided similar to FIG. 1 with differences to the stress suppressing feature 134 (FIG. 1). FIG. 3 has a stress suppressing feature 334 surrounding an NMOS transistor 302, having been formed perpendicular and parallel to the NMOS gate 308. In addition, the stress suppressing feature 334 has been formed perpendicular to the PMOS gate 320.

Thus, it has been discovered that the integrated circuit stress control system of the present invention furnish important and heretofore unknown and unavailable solutions, capabilities, and functional advantages for suppressing stress. The resulting process and configurations are straightforward, economical, uncomplicated, highly versatile, and effective, and can be implemented by adapting known components for ready manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations which fall within the scope of the included claims. All matters hithertofore set forth herein or shown in the accompanying drawings are to be interpreted in an illustrative and non-limiting sense.

What is claimed is:

1. An integrated circuit stress control system comprising;
providing a substrate;
forming a gate on the substrate;
forming a channel in the substrate;
forming a source/drain around the gate;
forming a shallow trench isolation in the substrate, the shallow trench isolation producing strain on the channel; and
forming a stress suppressing feature in the substrate.

2. The system of claim 1 wherein forming a channel in the substrate further comprises forming an n-type channel in the substrate.

3. The system of claim 1 wherein forming a channel in the substrate further comprises forming a p-type channel in the substrate.

4. The system of claim 1 further comprising forming a plurality of the stress suppressing features that are parallel to the gate, perpendicular to the gate, or both parallel and perpendicular to the gate.

5. The system of claim 1 further comprising adjusting the strain to a predetermined level by adjusting the position of the stress suppressing feature.

6. An integrated circuit stress control system comprising;
providing a substrate;
forming a plurality of complementary metal oxide semiconductors in the substrate;
forming a shallow trench isolation in the substrate, the shallow trench isolation producing strain in the complementary metal oxide semiconductors; and
forming a plurality of stress suppressing features in the substrate.

7. The system of claim 6 wherein forming a complementary metal oxide semiconductor further comprises forming a complementary metal oxide semiconductor with an n-type channel.

8. The system of claim 6 wherein forming a complementary metal oxide semiconductor further comprises forming a complementary metal oxide semiconductor with a p-type channel.

9. The system of claim 6 wherein forming a plurality of stress suppressing features further comprises forming the stress suppressing features parallel to the direction of the strain, perpendicular to the direction of the strain, or both parallel and perpendicular to the direction of the strain.

10. The system of claim 6 further comprising adjusting the strain to a predetermined level by adjusting the position of the stress suppressing feature.

11. An integrated circuit stress control system comprising;
a substrate;
a gate on the substrate;
a channel in the substrate;
a source/drain around the gate;
a shallow trench isolation in the substrate, the shallow trench isolation producing strain on the channel; and
a stress suppressing feature in the substrate.

12. The system of claim 11 wherein the channel in the substrate further comprises an n-type channel in the substrate.

13. The system of claim 11 wherein the channel in the substrate further comprises a p-type channel in the substrate.

14. The system of claim 11 further comprising a plurality of stress suppressing features in the substrate that are parallel to the gate, perpendicular to the gate, or both parallel and perpendicular to the gate.

15. The system of claim 11 wherein the stress suppressing feature further comprises a stress suppressing feature configured and positioned in the substrate to provide a predetermined level of strain.

16. An integrated circuit stress control system comprising:
a substrate;
a plurality of complementary metal oxide semiconductors in the substrate;
a shallow trench isolation in the substrate, the shallow trench isolation producing strain in the complementary metal oxide semiconductors; and
a plurality of stress suppressing features in the substrate.

17. The system of claim 16 wherein the complementary metal oxide semiconductor further comprises a complementary metal oxide semiconductor with an n-type channel.

18. The system of claim 16 wherein the complementary metal oxide semiconductor further comprises a complementary metal oxide semiconductor with a p-type channel.

19. The system of claim 16 wherein the stress suppressing features further comprise stress suppressing features formed parallel to the direction of the strain, perpendicular to the direction of the strain, or both parallel and perpendicular to the direction of the strain.

20. The system of claim 16 wherein the stress suppressing features further comprise stress suppressing features configured and positioned in the substrate to provide a predetermined level of strain.
